(19) United States
(12) Patent Application Publication
(10) Pub. No.: US 2013/0105834 A1
(43) Pub. Date: May 2, 2013

(54) WHITE LIGHT EMITTING DIODE DEVICE

(71) Applicant: JIAN-SHIHN TSANG, Tu-Cheng (TW)

(72) Inventor: JIAN-SHIHN TSANG, Tu-Cheng (TW)

(73) Assignee: HON HAI PRECISION INDUSTRY CO., LTD., Tu-Cheng (TW)

(21) Appl. No.: 13/433,198

(22) Filed: Mar. 28, 2012

(30) Foreign Application Priority Data
Oct. 27, 2011 (TW) 100139012

(51) Int. Cl. H01L 27/15

(52) U.S. Cl. 257/89; 257/E27.12

(57) ABSTRACT

A white light emitting diode device includes a substrate, a plurality of blue LED chips arranged on the substrate, an encapsulation covering the blue LED chips and a yellow phosphor absorbing part of blue light from the blue LED chips and emitting a yellow light. The blue light from the blue LED chips without being absorbed by the yellow phosphor is combined with the yellow light to form a white light. The blue LED chips have different peak wavelengths from each other. Differences between peak wavelengths of any two blue LED chips are no larger than a full width at half maximum of any one of the blue LED chips.

### BACKGROUND

1. Technical Field

The disclosure generally relates to a semiconductor device, and particularly to a white light emitting diode device.

2. Description of Related Art

Light emitting diodes (LEDs) have many beneficial characteristics, including low electrical power consumption, low heat generation, long lifetime, small volume, good impact resistance, fast response and excellent stability. These characteristics enable the LEDs to be used as light sources in electrical appliances and electronic devices.

Generally, a white light emitting diode device includes a blue LED chip and a yellow phosphor. The blue LED chips with different peak wavelengths have to use different types of yellow phosphor, or else white light emitting diode devices formed by the blue LED chips of different peak wavelengths and the same yellow phosphor will generate white lights each having an uneven color. In manufacturing of the blue LED chips, it is unavoidable for the blue LED chips to have different peak wavelengths. Generally, when differences of peak wavelengths of the two blue LED chips exceeds 2.5 nm, different types of phosphor are needed to form white light emitting diode devices each of which can generate a white light with a uniform color. Therefore, it is necessary to prepare different types of phosphors to match the blue LED chips with different wavelengths. Such a requirement is costly, time consuming and complex.

What is needed, therefore, is a white light emitting diode device to overcome the described limitations.

### BRIEF DESCRIPTION OF THE DRAWINGS

FIG. 1 is an isometric view of a white light emitting diode device in accordance with an embodiment of the present disclosure.

FIG. 2 is a cross sectional view of a white light emitting diode device in accordance with another embodiment.

FIG. 3 is a cross sectional view of a white light emitting diode device in accordance with still another embodiment.

FIG. 4 is a diagram showing light spectrums of blue LED chips with different wavelengths.

FIG. 5 is a CIE 1931 color space chromaticity diagram showing color coordinates of white lights emitted by different white LED devices wherein some white LED devices each having a blue light chip with a respective single wavelength and the others each having blue light chips with multiple wavelengths, wherein a difference between any two wavelengths of the multiple wavelengths is less than 10 nm.

FIG. 6 is similar to FIG. 5 showing color coordinates of white lights emitted by different white LED devices wherein some white LED devices each having a blue light chip with a respective single wavelength and the others each having blue light chips with multiple wavelengths, wherein a difference between any two wavelengths of the multiple wavelengths is less than 40 nm.

### DETAILED DESCRIPTION

Embodiments of a white light emitting diode device will now be described in detail below and with reference to the drawings.

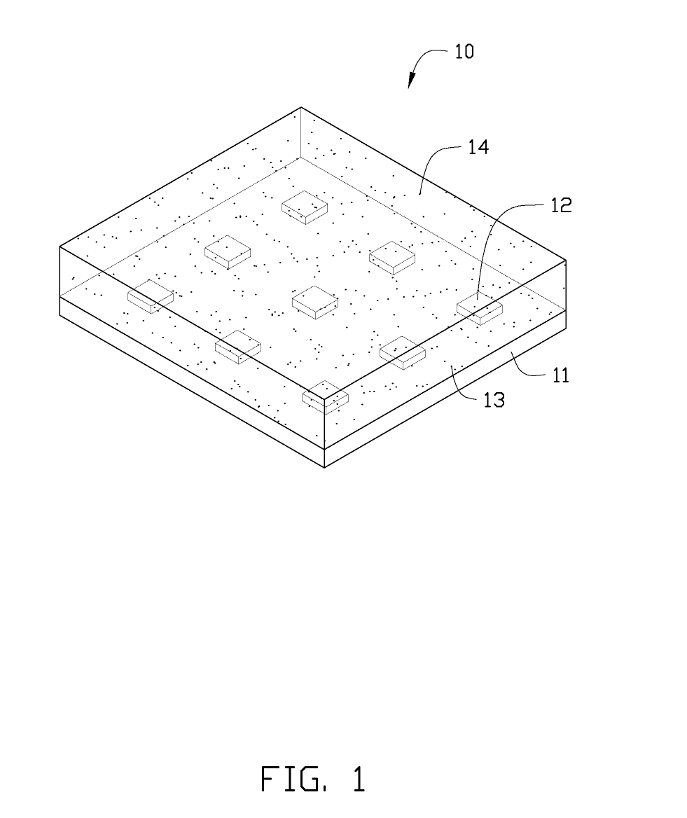

Referring to FIG. 1, a white light emitting diode device 10 includes a substrate 11, a plurality of blue LED chips 12 arranged on the substrate 11, an encapsulation 13 covering the blue LED chips 12, and a yellow phosphor 14 doped in the encapsulation 13.

The substrate 11 is plate-shaped. The blue LED chips 12 are arranged on an upper surface of the substrate 11. The blue LED chips 12 are arranged on the substrate 11 at a uniform interval and the peak wavelengths of the blue LED chips 12 gradually change with a fixedly increased (decreased) value in a predetermined sequence. Alternatively, the peak wavelengths of the blue LED chips 12 can be varied in random.

The blue LED chips 12 have peak wavelengths different from each other. In this embodiment, the blue LED chips 12 are electrically connected together in series, in parallel or in series-parallel. Each of the blue LED chips 12 has a full width at half maximum of about 25 nm. Furthermore, a difference between the peak wavelengths of any two blue LED chips 12 is no larger than the full width at half maximum of any one of the blue LED chips 12. That is, differences between the peak wavelengths of any two blue LED chips 12 are less than 25 nm.

The encapsulation 13 is formed on the upper surface of the substrate 11 to cover the blue LED chips 12, thereto prevent the blue LED chips 12 from being affected by the moisture or dust in atmosphere. The encapsulation 13 is made of silicone or epoxy resin.

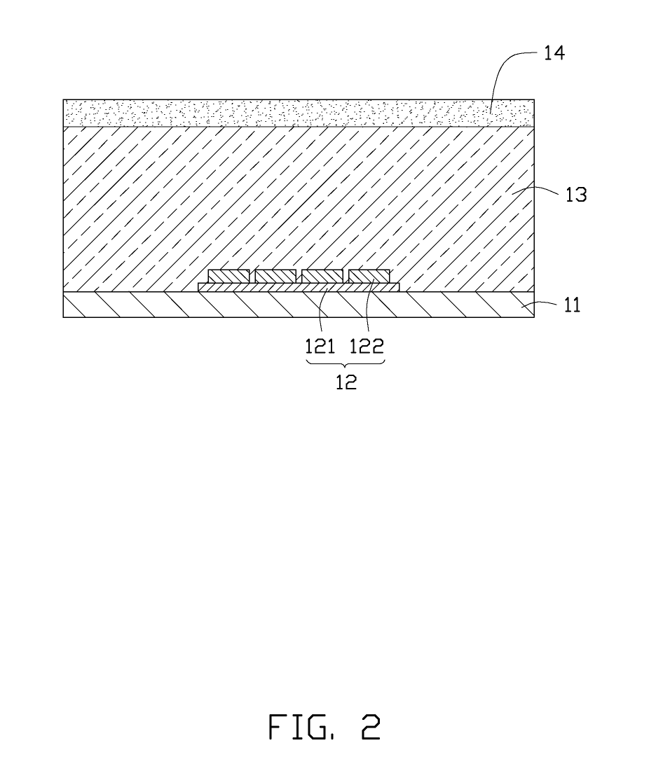

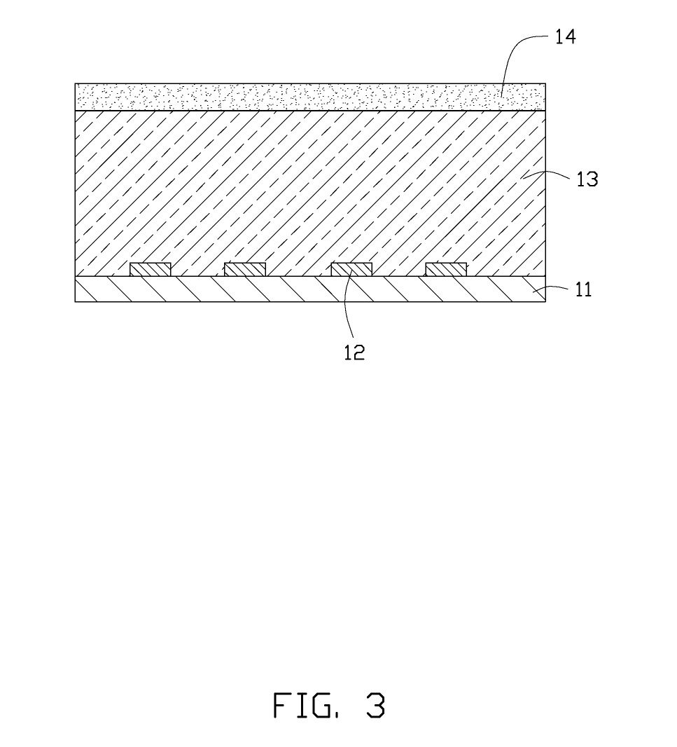

The yellow phosphor 14 is doped in the encapsulation 13. Part of blue light emitted from the blue LED chips 12 is absorbed by the yellow phosphor 14 and converted to a yellow light. The yellow light emitted by the yellow phosphor 14 and the remaining blue light of the blue LED chips 12 not absorbed by the yellow phosphor 14 are mixed together to form a white light. In this embodiment, the yellow phosphor 14 can be selected from a material consisting of sulfides, silicates, nitrides, nitrogen oxides, garnets, (SrCa)SiAlN and SiAlON. The yellow phosphor 14 is not limited to be doped in the encapsulation 13. As shown in FIGS. 2-3, in alternative embodiments, a yellow phosphor layer 14 is formed on an upper surface of the encapsulation 13. Therefore, the light from the blue LED chips 12 passes through the encapsulation 13 and then converted by the yellow phosphor layer 14 to be white light. In addition, as shown in FIG. 2, the blue LED chips 12 can also be LED dies 122 grown on a same wafer 121.

As described above, the white light emitting diode device 10 includes a plurality of the blue LED chips 12 with different peak wavelengths. Therefore, blue lights emitted by the blue LED chips 12 with different peak wavelengths are mixed together and then form a white light by mixing a yellow light emitted by the yellow phosphor.

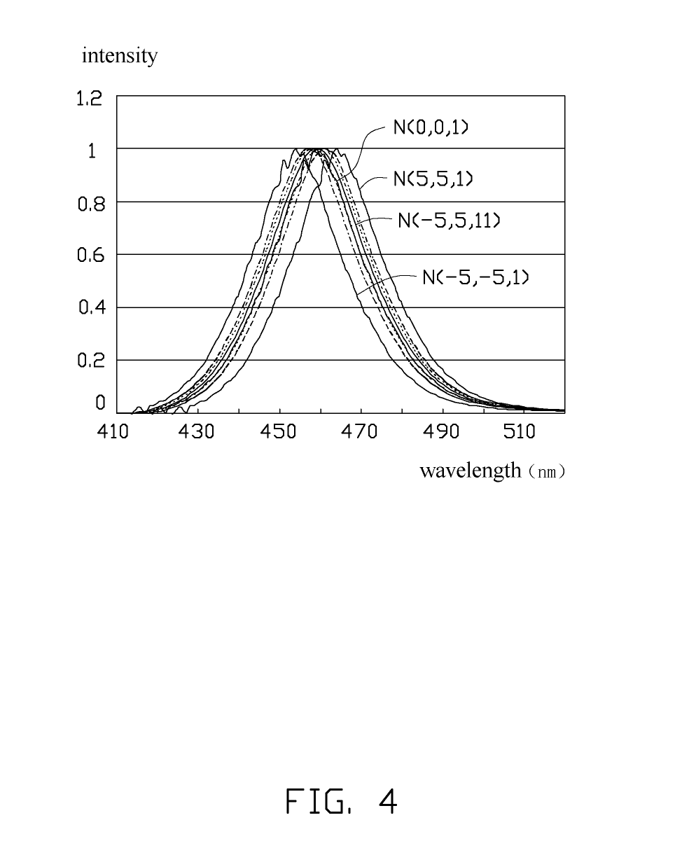

Referring to FIG. 4, light spectrums of blue LED chips each having a single peak wavelength and blue LED chips with multiple wavelengths are provided. In FIG. 4, N(0,0,1) represents a light spectrum of a basic light, which has a peak wavelength about 460 nm and a full width at half maximum about 25 nm. Similarly, N(−5,−5,1) represents a light spectrum of a white light deviated from the basic light in a negative direction for 5 nm and N(5,5,1) represents a light spectrum of a white light deviated from the basic light in a positive direction for 5 nm. That is, N(−5,−5,1) has a peak wavelength about 455 nm and a full width at half maximum about 25 nm, and N(5,5,1) has a peak wavelength about 465 nm and a full width at half maximum about 25 nm. In this embodiment, N(0,0,1), N(−5,−5,1) and N(5,5,1) are light spectrums of blue LED chips each having a single peak wavelength. N(−5,5,11) is a light spectrum of blue LED chips with multiple peak wavelengths, wherein the number “11” means eleven blue LED chips are included in the white light emitting diode device 10. The eleven blue LED chips have different peak wavelengths ranging from 455 nm to 465 nm at an interval of 1 nm. Each of the eleven blue LED chips has a full width at half maximum about 25 nm. Therefore, a light spectrum of N(a,b,n) represents that there are “n”-numbered blue LED chips which are combined together, wherein blue LED chips have different peak wavelengths ranging from (460+a)nm to (460+b)nm at an interval of 1 nm. “n” can be determined by n=b−a+1.

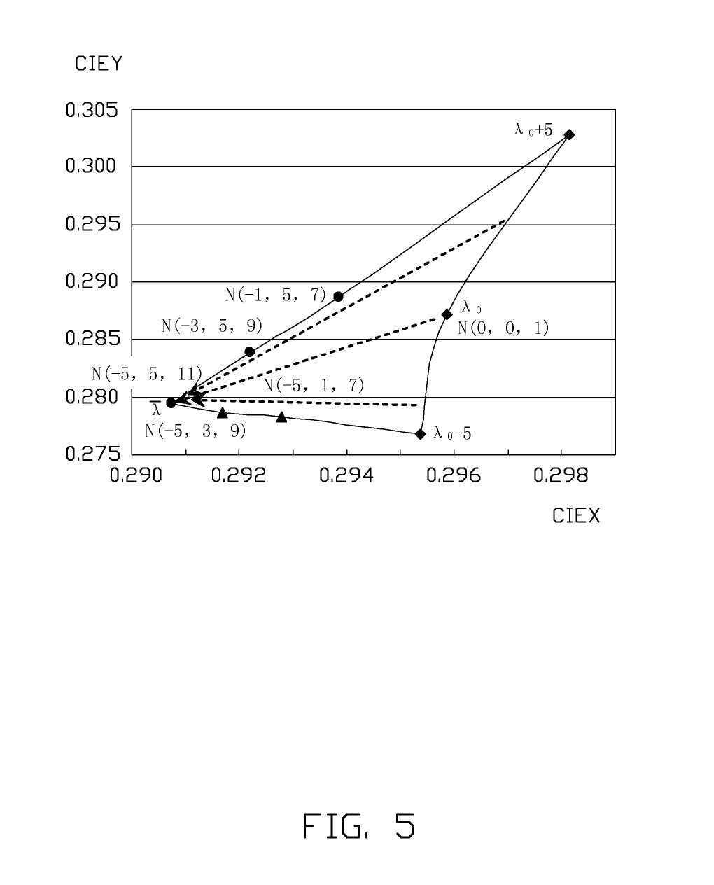

Referring to FIG. 5, color coordinates of white light emitting diode devices each using a blue LED chip with a respective single peak wavelength and white light emitting diode devices each using blue LED chips with multiple peak wavelengths are provided, wherein a difference between any two peak wavelengths is less than 10 nm. λ₀ represents a color coordinate of a white light formed by a white light emitting diode device using a blue LED chip with a single peak wavelength of 460 nm and a yellow phosphor, λ₀−5 represents a color coordinate of a white light formed by a white light emitting diode device using a blue LED chip with a single peak wavelength of 455 nm and the yellow phosphor, and λ₀+5 represents a color coordinate of a white light formed by a white light emitting diode device using a blue LED chip with a single peak wavelength of 465 nm and the yellow phosphor. According to FIG. 5, based on the CIE 1931 color space chromaticity diagram, λ₀ has a coordinate point CIE(0.2959, 0.2872); λ₀−5 has a coordinate point CIE(0.2954, 0.2768); λ₀+5 has a coordinate point CIE (0.2981, 0.3027). For white lights formed by white light emitting diode devices each using blue LED chips with multiple peak wavelengths and the yellow phosphor, N(−1,5,7) has a coordinate point CIE(0.2938, 0.2887); N(−5,1,7) has a coordinate point CIE(0.2928, 0.2783); N(−3,5,9) has a coordinate point CIE(0.2922, 0.2839); N(−5,3,9) has a coordinate point CIE(0.2917, 0.2787); N(−5,5,11) has a coordinate point CIE(0.2907, 0.2794). As shown in FIG. 5, variations in CIEy of white light emitting diode devices each using a blue LED chip with a respective single peak wavelength is larger than that of the white light emitting diode devices each using blue LED chips with multiple peak wavelengths. It means that the white light emitting diode devices using blue LED chips with multiple peak wavelengths will have a narrower distribution of color coordinates than the white light emitting diode devices each using a blue LED chip with a respective single peak wavelength. Because white light is more sensible to the change in CIEy than the change in CIEx, the white light emitting diode devices using blue LED chips with multiple peak wavelengths will have a better color coordinate distribution than the white light emitting diode devices each using a blue LED chip with a respective single peak wavelength. Therefore, even if the blue LED chips 12 manufactured in a same process have different peak wavelengths, it is unnecessary to prepare different types of phosphor to obtain white light with a uniform distribution of color coordinates.

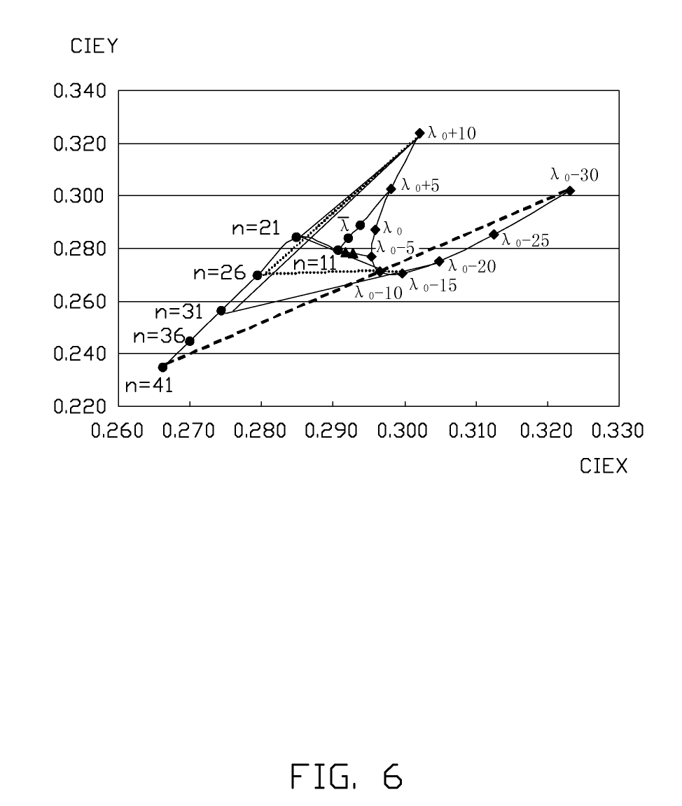

Referring to FIG. 6, color coordinates of white light emitting diode devices each using a blue LED chip with a respective single peak wavelength and white light emitting diode devices each using blue LED chips with multiple peak wavelengths are provided, wherein a difference between any two peak wavelengths is less than 40 nm. In FIG. 6, n=11 represents a color coordinate of a white light generated by a white light emitting diode device using eleven blue LED chips having different peak wavelengths ranging from 455 nm to 465 nm at an interval of 1 nm; n=21 represents a color coordinate of a white light generated by a white light emitting diode device using twenty one blue LED chips having different peak wavelengths ranging from 450 nm to 470 nm at an interval of 1 nm; n=26 represents a color coordinate of a white light generated by a white light diode emitting device using twenty six blue LED chips having different peak wavelengths ranging from 445 nm to 470 nm at an interval of 1 nm. Similarly, n=31, n=36, n=41 represents a color coordinate of a white light generated by white light diode emitting devices using blue LED chips having different peak wavelengths ranging from 440 nm to 470 nm, from 435 nm to 470 nm and from 430 nm to 470 nm at an interval of 1 nm respectively. Differences between color coordinates of white lights of the white light emitting diode devices using a blue LED chip with a respective single peak wavelength and using blue LED chips with multiple peak wavelengths are shown in label 1.

Label 1. differences between color coordinates of white lights in FIG. 6

| Wavelength | | | | | ABS(δ(CIEx)- | ABS(δ(CIEy)- |
|---|---|---|---|---|---|---|
| range | δ(CIEx) | δ(CIEy) | δ(CIEx(R)) | δ(CIEy(R)) | δ(CIEx(R))) | δ(CIEy(R))) |
| 10 | 0.0028 | 0.0260 | 0.0074 | 0.0233 | 0.00463 | 0.00266 |
| 20 | 0.0056 | 0.0525 | 0.0172 | 0.0394 | 0.01166 | 0.01308 |
| 25 | 0.0068 | 0.0532 | 0.0227 | 0.0540 | 0.01595 | 0.00079 |
| 30 | 0.0095 | 0.0532 | 0.0305 | 0.0673 | 0.02100 | 0.01403 |
| 35 | 0.0172 | 0.0532 | 0.0426 | 0.0789 | 0.02543 | 0.02565 |
| 40 | 0.0278 | 0.0532 | 0.0570 | 0.0888 | 0.02920 | 0.03556 |

In label 1, δ(CIEx) represents differences between the color coordinates in CIEx of white lights generated by the white light emitting diode devices each using a blue chip having a respectively single peak wavelength when differences between the peak wavelengths of the blue LED chips thereof are respectively equal to 10 nm, 20 nm, 25 nm, 30 nm, 35 nm and 40 nm; δ(CIEy) represents differences between the color coordinates in CIEy of white lights generated by the white light emitting diode devices each using a blue chip having a respective single peak wavelength when differences between the peak wavelengths of the blue LED chips thereof are respectively equal to 10 nm, 20 nm, 25 nm, 30 nm, 35 nm and 40 nm; δ(CIEx(R)) represents differences between the color coordinates in CIEx of white lights generated by the white light emitting diode devices each using blue LED chips with multiple peak wavelengths when differences between the peak wavelengths of the blue LED chips thereof are respectively equal to 10 nm, 20 nm, 25 nm, 30 nm, 35 nm and 40 nm; δ(CIEy(R)) represents differences between the color coordinates in CIEy of white lights generated by the white light emitting diode devices each using blue LED chips with multiple peak wavelengths when differences between the peak wavelengths of the blue LED chips thereof are respectively equal to 10 nm, 20 nm, 25 nm, 30 nm, 35 nm or 40 nm; ABS(δ(CIEx)−δ(CIEx(R))) represents an absolute value between a difference of δ(CIEx) and δ(CIEx(R)); ABS(δ(CIEy)−δ(CIEy(R))) represents an absolute value between a difference of δ(CIEy) and δ(CIEy(R)).

According to label 1, when a difference between the peak wavelengths of the white lights is equal to 10 nm or 20 nm, the δ(CIEy(R)) is less than the δ(CIEy). When a difference between the peak wavelengths of the white lights is equal to 25 nm, the δ(CIEy(R)) is 0.0540, which is slightly more than the δ(CIEy). However, when a difference between peak wavelengths of the white lights is equal to 30 nm, 35 nm or 40 nm, the δ(CIEy(R)) is 0.0673, 0.0789 and 0.0888 respectively, whereby the values of δ(CIEy(R)) are much more than the values of δ(CIEy). Therefore, when a difference between the peak wavelengths of the white lights is equal to or less than 25 nm, the variations between the color coordinates in CIEy of white lights generated by white light emitting diode devices each using blue LED chips with multiple wavelengths are acceptable even when the white light emitting diode devices use an encapsulation having the same yellow phosphor to cover the blue LED chips thereof.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A white light emitting diode device, comprising:
a substrate;
a plurality of blue LED chips arranged on the substrate, the blue LED chips having peak wavelengths different from each other, differences between peak wavelengths of any two blue LED chips being no larger than a full width at half maximum of any one of the blue LED chips;
an encapsulation formed on the substrate and covering the blue LED chips; and
a phosphor for absorbing part of blue light from the blue LED chips and emitting a different color light, blue light from the blue LED chips not absorbed by the phosphor mixing with the said different color light to form a white light.

2. The white light emitting diode device of claim 1, wherein differences between peak wavelengths of any two blue LED chips is no larger than 25 nm.

3. The white light emitting diode device of claim 1, wherein peak wavelengths of the blue LED chips vary at a fixed interval.

4. The white light emitting diode device of claim 3, wherein peak wavelengths of the blue LED chips range from 445 nm to 470 nm.

5. The white light emitting diode device of claim 1, wherein the blue LED chips form series connections, parallel connections or series-parallel connections with each other.

6. The white light emitting diode device of claim 1, wherein the phosphor is doped into the encapsulation.

7. The white light emitting diode device of claim 1, wherein the phosphor is a phosphor layer covering on a surface of the encapsulation away from the blue LED chips.

8. The white light emitting diode device of claim 1, wherein the phosphor is selected from a material consisting of sulfides, silicates, nitrides, nitrogen oxides, garnets, (SrCa)SiAlN and SiAlON.

9. The white light emitting diode device of claim 1, wherein the encapsulation is made of silicone or epoxy resin.

10. The white light emitting diode device of claim 2, wherein peak wavelengths of the blue LED chips vary at a fixed interval.

11. The white light emitting diode device of claim 10, wherein peak wavelengths of the blue LED chips range from 445 nm to 470 nm.

12. The white light emitting diode device of claim 2, wherein the blue LED chips form series connections, parallel connections or series-parallel connections with each other.

13. The white light emitting diode device of claim 2, wherein the phosphor is doped into the encapsulation.

14. The white light emitting diode device of claim 2, wherein the phosphor is a phosphor layer covering on a surface of the encapsulation away from the blue LED chips.

15. The white light emitting diode device of claim 2, wherein the phosphor is selected from a material consisting of sulfides, silicates, nitrides, nitrogen oxides, garnets, (SrCa)SiAlN and SiAlON.

16. A white light emitting diode device, comprising:
a substrate;
a plurality of blue LED chips arranged on the substrate, the blue LED chips having peak wavelengths different from each other, differences between peak wavelengths of any two blue LED chips being no larger than a full width at half maximum of any one of the blue LED chips;
an encapsulation formed on the substrate and covering the blue LED chips; and
a yellow phosphor for absorbing part of blue light from the blue LED chips and emitting a yellow light, blue light from the blue LED chips not absorbed by the yellow phosphor mixing with the yellow light to form a white light.
